(19) United States
(12) Patent Application Publication
(10) Pub. No.: US 2010/0277214 A1
(43) Pub. Date: Nov. 4, 2010

(54) DEVICE AND METHOD FOR SIGNAL GENERATION

(75) Inventors: Tsung-Hau Chang, Hsinchu City (TW); Kuo-Ching Hsu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NOVATEK MICROELECTRONICS CORP., Hsinchu (TW)

(21) Appl. No.: 12/508,576

(22) Filed: Jul. 24, 2009

(30) Foreign Application Priority Data
Apr. 30, 2009 (TW) 98114406

(51) Int. Cl. H03K 5/04

(52) U.S. Cl. 327/175

(57) ABSTRACT

A signal generator and a method thereof for generating signals are provided. The signal generator includes a pulse width signal generation module and a signal generating module. The pulse width signal generation module generates a first pulse width signal according to a first pulse signal and a second pulse signal. A first signal with a first duty ratio is generated by the signal generating module based on the first pulse width signal. The first duty ratio is equal to a product of a duty ratio of the first pulse signal and a duty ratio of the second pulse signal.

### CROSS-REFERENCE TO RELATED APPLICATION

This application claims the priority benefit of Taiwan application serial no. 98114406, filed on Apr. 30, 2009. The entirety of the above-mentioned patent application is hereby incorporated by reference herein and made a part of specification.

### BACKGROUND OF THE INVENTION

1. Field of the Invention

The present invention is related to a signal generator, and particularly related to a signal generator and a signal generation method thereof for generating an output signal according to information related to duty ratios of a plurality of input signals.

2. Description of Related Art

A periodic signal with a frequency loaded on another periodic signal with a specific frequency is commonly applied in communications and related fields. Wherein, a multiplication of sinusoidal waves may be achieved easily by a mixer, further resulting in frequency addition and subtraction. In addition, a multiplication of amplitudes of two signals may also be easily achieved. However, there is currently lacking of further discussion in the industry on an issue regarding how to convert two or more input pulse signals with different frequencies and different amplitudes to an output pulse signal, such that a duty ratio of the converted output pulse signal is equal to a product of duty ratios of the input pulse signals.

### SUMMARY OF THE INVENTION

The present invention provides a signal generator, which may generate a signal having multiplication information of duty ratios of a plurality of pulse signals.

The present invention provides a signal generating method, through extracting information of the duty ratios of the pulse signals, acquiring the signal having multiplication information of the duty ratios of the pulse signals.

The present invention proposes a signal generator, including a pulse width signal generation module and a signal generation module. The pulse width signal generation module generates a first pulse width signal according to a first pulse signal and a second pulse signal. The signal generation module generates a first signal with a first duty ratio according to the first pulse width signal, wherein the first duty ratio is equal to a product of a duty ratio of the first pulse signal and a duty ratio of the second pulse signal.

In an embodiment of the present invention, the pulse width signal generation module includes a first pulse signal conversion unit, a multiplication unit, a second pulse signal conversion unit. The first pulse signal conversion unit receives the first pulse signal and converting the first pulse signal to a second pulse width signal. The multiplication unit, coupled to the first pulse signal conversion unit, receives the second pulse width signal and the second pulse signal, and multiplies the second pulse width signal and the second pulse signal to generate a third pulse signal. In addition, the second pulse signal conversion unit, coupled to the multiplication unit and the signal generation module, receives the third pulse signal to convert the third pulse signal to the first pulse width signal.

In an embodiment of the present invention, the second pulse width signal is an analog signal, a ratio of a voltage level of the second pulse width signal to a voltage level of a peak of the first pulse signal is equal to the duty ratio of the second pulse signal.

In an embodiment of the present invention, the first pulse width signal is an analog signal, and a ratio of a voltage level of the first pulse width signal to a voltage level of a peak of the second pulse signal is equal to the product of the duty ratio of the first pulse signal and the duty ratio of the second pulse signal.

In an embodiment of the present invention, the multiplication unit is an analog mixer or a digital multiplier.

In an embodiment of the present invention, the second pulse signal conversion unit includes a first low pass filter which is coupled to the multiplication unit and the signal generation module, receiving the third pulse signal and filtering the third pulse signal to generate the first pulse width signal, wherein the third pulse signal is an analog signal, and the first pulse width signal is a direct current (DC) signal.

In an embodiment of the present invention, the first pulse signal conversion unit includes a second low pass filter which is coupled to the multiplication unit, receiving the first pulse signal and filtering the first pulse signal to generate the second pulse width signal, wherein the first pulse signal is an analog signal, and the first pulse width signal is a DC signal.

In an embodiment of the present invention, the second pulse signal conversion unit further includes an analog-to-digital converter (ADC) which is coupled to the first low pass filter and the signal generation module, receiving the first pulse width signal and converting the first pulse width signal to a digital signal.

In an embodiment of the present invention, the first pulse signal conversion unit includes a digital-to-analog converter (DAC) which is coupled to the multiplication unit, receiving the first pulse signal and converting the first pulse signal to the second pulse width signal, wherein the first pulse signal is a digital signal, and the second pulse width signal is a DC signal.

In an embodiment of the present invention, the pulse width signal generation module includes the multiplication unit which is coupled to the signal generation module. The multiplication unit receives the first pulse signal and the second pulse signal, and multiplies the first pulse signal and the second pulse signal to generate the first pulse width signal, wherein the second pulse signal is a digital signal.

In an embodiment of the present invention, the pulse width signal generation module further includes the ADC which is coupled to the multiplication unit and the signal generation module, receiving the first pulse width signal and converting the first pulse signal to an analog signal.

In an embodiment of the present invention, the pulse width signal generation module further includes a third low pass filter and the ADC. The third low pass filter receives the first pulse signal and filters the first pulse signal to generate the second pulse width signal. Wherein the first pulse signal is an analog signal and the second pulse width signal is a DC signal. In addition, the ADC is coupled to the third low pass filter and the multiplication unit, receiving the second pulse width signal and converting the second pulse width signal to a digital signal.

In an embodiment of the present invention, the signal generation module includes an oscillator and a comparison unit. The oscillator periodically generates a second signal. The comparison unit is coupled between the pulse width signal generation module and the oscillator. The comparison unit compares a voltage level of the first pulse width signal and a voltage level of the second signal to generate a first signal, wherein the first pulse width signal and the second signal are analog signals.

In an embodiment of the present invention, the signal generation module includes a clock signal generation unit, a counting unit, and a digital signal generation unit. The clock signal generation unit generates a clock signal. The counting unit is coupled o the clock signal generator unit and counts pluses of the clock signal to generate a counting value. In addition, the digital signal generation unit is coupled between the pulse width signal generation module and the counting unit, and generates the first signal according to the first pulse width signal and the counting value, wherein the first pulse width signal is a digital signal.

The present invention proposes a signal generating method, including following steps. First, the first pulse width signal is generated according to the first pulse signal and the second pulse signal. Then, the first signal with the first duty ratio is generated according to the first pulse width signal, wherein the first duty ratio is equal to the product of the duty ratio of the first pulse signal and the duty ratio of the second pulse signal.

In an embodiment of the present invention, the step of generating the first pulse width signal includes: first, the first pulse signal is converted to the second pulse signal. Then, the second pulse width signal and the second pulse signal are multiplied to generate a third pulse signal. Further, the third pulse signal is converted to the first pulse width signal.

In an embodiment of the present invention, the step of generating the first signal includes: first, the second signal is periodically generated. Then, the voltage level of the first pulse width signal is compared with the voltage level of the second signal to generate the first signal, wherein the first pulse width signal and the second signal are analog signals.

In an embodiment of the present invention, the step of generating the first pulse width signal includes multiplying the first pulse signal and the second pulse signal to generate the first pulse width signal.

In an embodiment of the present invention, the step of generating the first signal includes: first, the counting value is generated by counting pulses of the clock signal. Then, the first signal is generated according to the first pulse width signal and the counting value, wherein the first pulse width signal is a digital signal.

According to the above, the present invention generates the signal having multiplication information of the duty ratios of a plurality of pulse signals through extracting information of the duty ratios of the pulse signals.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram illustrating a signal generator according to a first embodiment of the present invention.

FIG. 2 is a flow chart illustrating a signal generation method according to the first embodiment of the present invention.

FIG. 3 is a block diagram illustrating a signal generator according to a second embodiment of the present invention.

FIG. 4 is a block diagram illustrating a signal generator according to a third embodiment of the present invention.

FIGS. 5A-5D are schematic diagrams illustrating signal waveforms according to the third embodiment of the present invention.

FIG. 6 is a block diagram illustrating a signal generator according to a fourth embodiment of the present invention.

FIG. 7 is a block diagram illustrating a signal generator according to a fifth embodiment of the present invention.

FIG. 8 is a schematic diagram illustrating digital signals according to a fifth embodiment of the present invention.

FIG. 9 is a block diagram illustrating a signal generator according to a sixth embodiment of the present invention.

FIG. 10 is a block diagram illustrating a signal generator according to a seventh embodiment of the present invention.

FIG. 11 is a block diagram illustrating a signal generator according to an eighth embodiment of the present invention.

FIG. 12 is a block diagram illustrating a signal generator according to a ninth embodiment of the present invention.

FIG. 13 is a block diagram illustrating a signal generator according to a tenth embodiment of the present invention.

FIG. 14 is a schematic diagram illustrating an application of a signal generator for a monitor brightness adjustment according to an embodiment of the present invention.

### DESCRIPTION OF EMBODIMENTS

Descriptions of the present invention are given with reference to the embodiments illustrated with accompanied drawings wherein same or similar parts are denoted with same reference numerals.

### The First Embodiment

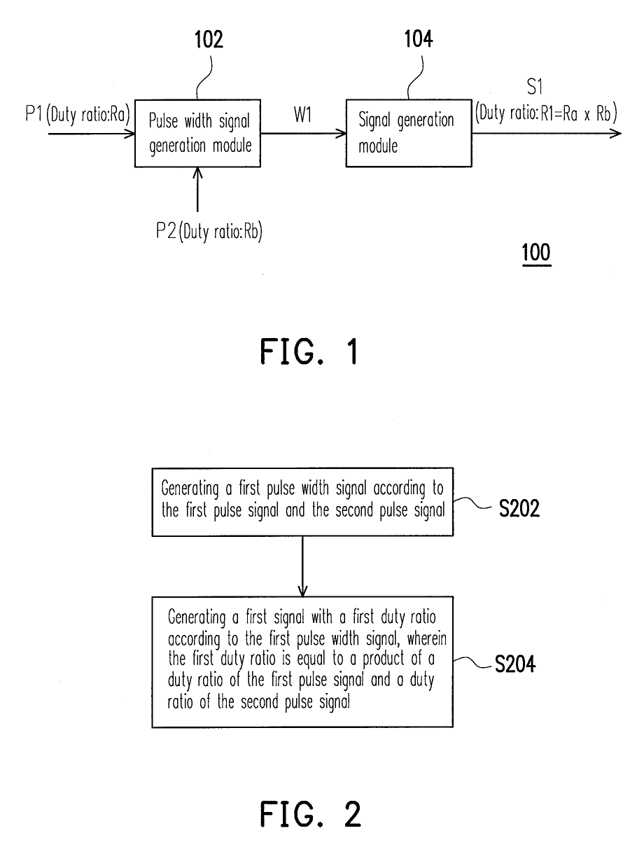

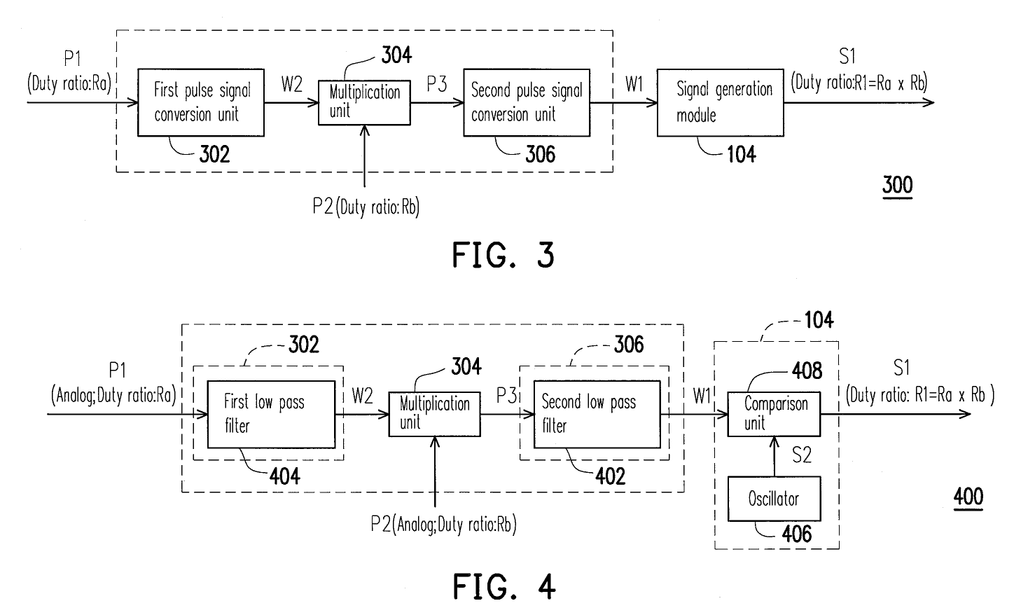

FIG. 1 is a block diagram illustrating a signal generator according to a first embodiment of the present invention. The present invention proposes a signal generator 100, including a pulse width signal generation module 102 and a signal generation module 104. The pulse width signal generation module 102 is coupled to the signal generation module 104. FIG. 2 is a flow chart illustrating a signal generation method according to the first embodiment of the present invention. The signal generation method will be described below referring to both FIG. 1 and FIG. 2.

First, the pulse width signal generation module 102 generates a first pulse width signal W1 according to a first pulse signal P1 and a second pulse signal P2 (step S202). Then, the signal generation module 104 generates a first signal S1 with a first duty ratio R1 according to the first pulse width signal W1 (step S204), wherein the first duty ratio R1 is equal to a product of a duty ratio Ra of the first pulse signal P1 and a duty ratio Rb (i.e., Ra×Rb) of the second pulse signal P2.

### The Second Embodiment

In the present embodiment, the pulse width signal generation module 102 may include two pulse signal conversion units and a multiplication unit. Referring to FIG. 3, FIG. 3 is a block diagram illustrating a signal generator 300 according to a second embodiment of the present invention. The pulse width signal generation module 102 of the signal generator 300 includes a first pulse signal conversion unit 302, a multiplication unit 304, and a second pulse signal conversion unit 306. The first pulse signal conversion unit 302 is coupled to the multiplication unit 304, and the second pulse signal conversion unit 306 is coupled to the multiplication unit 304 and the signal generation module 104. Wherein, the multiplication unit 304 is an analog mixer.

In the present embodiment, in the step S202, a process of generating the first pulse width signal W1 may be divided into: first, the first pulse signal conversion unit 302 receives the first pulse signal P1 and converts the first pulse signal P1 to the second pulse width signal W2. Then, the multiplication unit 304 receives the second pulse width signal W2 and the second pulse signal P2, and multiplies the second pulse width signal W2 and the second pulse signal P2 to generate the third pulse signal P3. Finally, the second pulse conversion unit 306 receives the third pulse signal P3 and converts the third pulse signal P3 to the first pulse width signal W1.

Further, as illustrated in the step S204, the signal generation module 104 is made to generate the first signal S1 with the first duty ratio R1 according to the first pulse width signal W1. Wherein, the first duty ratio R1 is equal to the product of the duty ratio Ra of the first pulse signal P1 and the duty ratio Rb of the second pulse signal P2.

### The Third Embodiment

FIG. 4 is a block diagram illustrating a signal generator according to a third embodiment of the present invention. Referring to FIG. 4, a difference between the signal generator 400 of the present embodiment and the signal generator 200 of the second embodiment is that the second pulse signal conversion unit 306 includes a first low pass filter 402, and the first pulse signal conversion unit 302 includes a second low pass filter 404. Wherein, the first low pass filter 402 is coupled between the multiplication unit 304 and the signal generation module 104, and the second low pass filter 404 is coupled to the multiplication unit 304. On the other hand, in the present embodiment, the first pulse signal P1 and the second pulse signal P2 are analog signals. The signal generation module 104 includes an oscillator 406 and a comparison unit 408. The comparison unit 408 is coupled to the first low pass filter 402 and the oscillator 406.

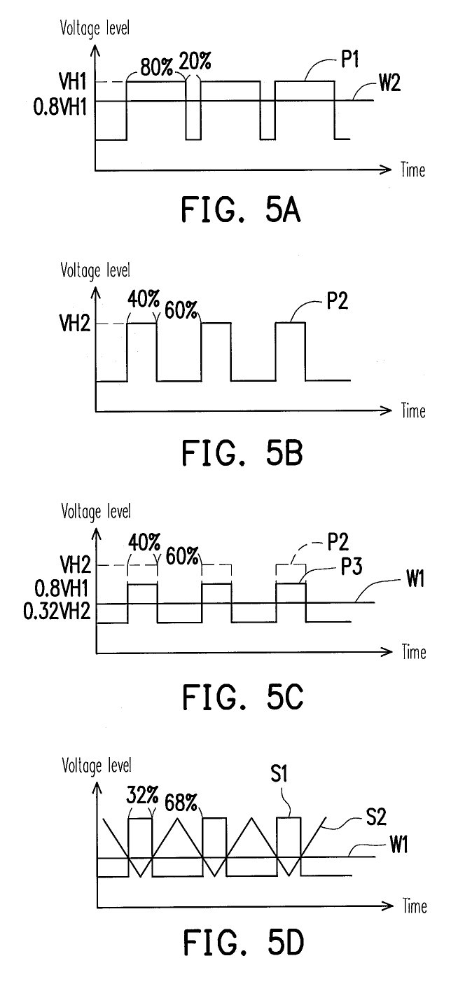

FIGS. 5A-5D are schematic diagrams illustrating signal waveforms according to the third embodiment of the present invention. The signal generation method of the third embodiment will be described in details below referring to FIG. 4 and FIGS. 5A-5D. In the present embodiment, the step S202 includes following processes: first, the second low pass filter 404 receives the first pulse signal P1 and filters the first pulse signal P1 to generate the second pulse width signal W2. Wherein, the second pulse width signal W2 is a direct current (DC) signal (i.e. an analog signal).

It should be noted that a ratio of a voltage level of the second pulse width signal W2 in FIG. 5A to a voltage level of a peak of the first pulse signal P1 is equal to the duty ratio Ra of the first pulse signal P1. For example, if the duty ratio Ra of the first pulse signal P1 is 80%, and the voltage level of the peak of the first pulse signal P1 is VH1, then the voltage level of the second pulse width signal W2 which is generated after filtering of the second low pass filter 404 is equal to 0.8VH1.

Next, the multiplication unit 304 receives the second pulse width signal W2 and the second pulse signal P2, and multiplies the second pulse width signal W2 and the second pulse signal P2 (i.e. an analog signal) to generate the third pulse signal P3 (i.e. an analog signal), wherein a ratio of a peak voltage level of the third pulse signal P3 to a peak voltage level of the second pulse signal P2 is equal to the duty ratio Ra of the first pulse signal P1. In addition, a frequency of the third pulse signal P3 is equal to a frequency of the second pulse signal P2, and a duty ratio of the third pulse signal P3 is equal to the duty ratio of the second pulse signal P2. For example, assuming the peak voltage level of the second pulse signal P2 is VH2, then the voltage level of the third pulse signal P3 which is generated through multiplication of the second pulse width signal W2 and the second pulse signal P2 by the multiplication unit 304 is equal to 0.8VH2 (as illustrated in FIG. 5C).

Further, the first low pass filter 402 receives the third pulse signal P3 and filters the third pulse signal P3 to generate the first pulse width signal W1. Wherein, the first pulse width signal W1 is a DC signal (i.e. an analog signal).

It should be noted that a ratio of the voltage level of the first pulse width signal W1 in FIG. 5C to the peak voltage level of the second pulse signal P2 is equal to the product of the duty ratio Ra of the first pulse signal P1 and the duty ratio Rb of the second pulse signal P2. For example, assuming the voltage level of the peak of the second pulse signal P2 is VH2, then the voltage level of the first pulse width signal W1 which is generated after the filtering of the first low pass filter 402 is equal to 0.32VH2.

On the other hand, the oscillator 406 of the signal generation module 104 may periodically generate a second signal S2. The comparison unit 408 compares the voltage level of the first pulse width signal W1 and a voltage level of the second signal S2 so as to generate a first signal S1 in the step S204, wherein the second signal S2 is an analog signal.

For example, the second signal S2 may be the saw tooth wave in FIG. 5D, and the first signal S1 may be the pulse wave in FIG. 5D. When the comparison unit 408 determines that the voltage level of the first pulse width signal W1 (i.e. a DC signal) is higher than the voltage level of the second signal S2 after the comparison, the comparison unit 408 outputs a pulse signal, i.e. the first signal S1, with an identical amplitude of the second signal S2. On the contrary, when the comparison unit 408 determines that the voltage level of the first pulse width signal W1 is lower than the voltage level of the second signal S2 after the comparison, the voltage level of the first signal S1 output by the comparison unit 408 is low.

It should be noted that the first duty ratio R1 of the first signal S1 in FIG. 5D is equal to the product of the duty ratio Ra of the first pulse signal P1 and the duty ratio Rb of the second pulse signal P2. For example, if the duty ratio Ra of the first pulse signal P1 is 80%, and the duty ratio Rb of the second pulse signal P2 is 40%, then the first duty ratio R1 of the first signal S1 which is generated after multiplication of the two pulse signals by the multiplication unit 304 is equal to 32% (0.8*0.4*100%=32%).

A time of the signal generated by the comparison unit 408 staying in a high voltage level may be changed proportionally according to the rising and falling of the voltage level of the DC signal. When the voltage level of the first pulse width signal W1 rises, a time of the voltage level of the first pulse width signal W1 (i.e. a DC signal) higher than the voltage level of the second signal S2 becomes longer, so the time of the first signal S1 staying in the high voltage level also becomes longer. On the contrary, when the voltage level of the first pulse width signal W1 falls, the time of the voltage level of the first pulse width signal W1 higher than the voltage level of the second signal S2 becomes shorter, so the time of the first signal S1 staying in the high voltage level also becomes shorter.

The voltage level of the first pulse width signal W1 is associated with the first pulse signal P1 and the duty ratio Rb of the second pulse signal P2. Therefore, the first signal S1 with the first duty ratio R1 may be generated by comparing the second signal S2 and the first pulse width signal W1. In addition, the signal generator 400 may adjust amplitude and a frequency of the second signal S2 output by the oscillator 406 so as to acquire the first signal S1 with a different frequency and different amplitude.

It should be noted that the second signal S2 output by the oscillator 406 in the present embodiment is not limited to the saw tooth wave in FIG. 5D, any waveform may be the second signal S2 so long as the waveform can be compared with the first pulse width signal W1 to generate the first signal S1, wherein the time of the voltage level of the first signal S1 staying in the high level is changed proportionally according to a change in the first pulse width signal W1.

### The Fourth Embodiment

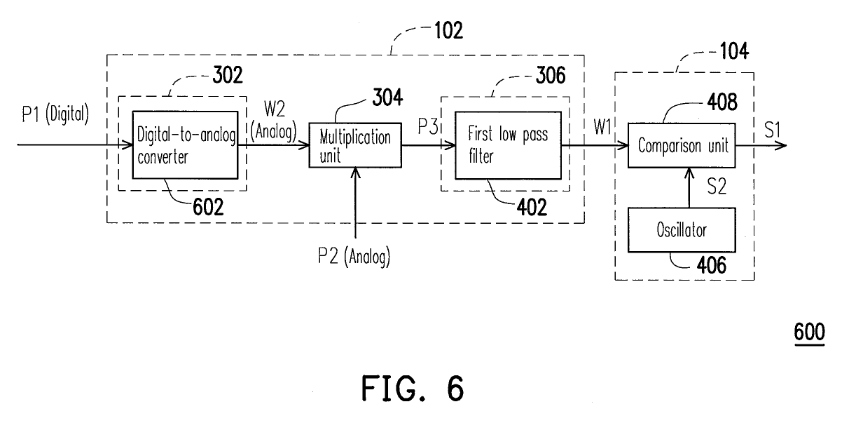

FIG. 6 is a block diagram illustrating a signal generator according to a fourth embodiment of the present invention. Referring to FIG. 6, a difference of the present embodiment and the third embodiment is that the first pulse signal P1 is a digital signal (e.g., a digital code), and the second low pass filter 404 of the signal generator 400 is replaced by a digital-to-analog converter (DAC) 602 of a signal generator 600. Wherein, the DAC 602 is coupled to the multiplication unit 304. In the step S202 of the present embodiment, before multiplication of the second pulse width signal W2 and the second pulse signal P2, the first pulse signal P1 (i.e. a digital signal) is first converted to the second pulse width signal W2 (i.e. a DC signal) by the DAC 602. For example, assuming the firs pulse signal P1 records information of the duty ratio Ra thereof by a digital code “11000000” (i.e., a decimal number with a value of 192) of 8 bits, then the duty ratio Ra of the first pulse signal P1 is 75% (192 divided by 256 is equal to 0.75). Therefore, after the DAC 602 receives the first pulse signal P1, the first pulse signal P1 is converted to the second pulse width signal W2 (i.e. a DC signal) with a voltage level of the duty ratio of 75%. Further, the steps of generating the third pulse signal P3, the first pulse width signal W1 and the first signal S1 are identical to the third embodiment, so they will not be described herein.

### The Fifth Embodiment

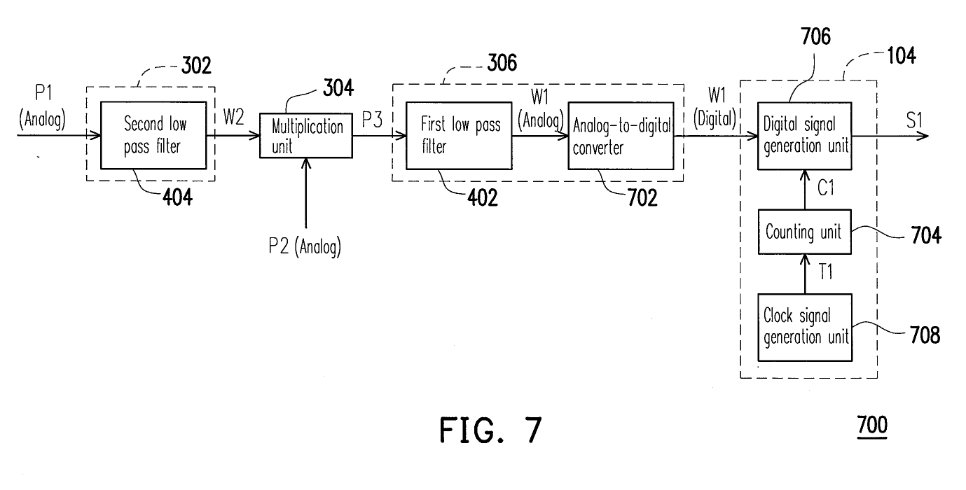

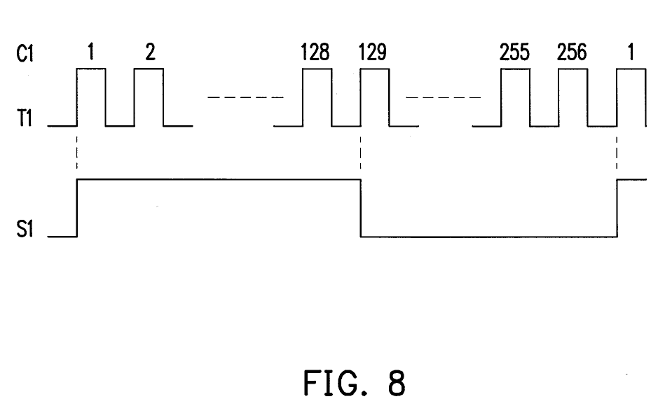

FIG. 7 is a block diagram illustrating a signal generator according to a fifth embodiment of the present invention. Referring to FIG. 7, a difference of a signal generator 700 of the present embodiment and the signal generator 600 of the fourth embodiment is that the first pulse signal P1 is an analog signal, and in addition, the second pulse signal conversion unit 306 further includes an analog-to-digital converter (ADC) 702. The ADC 702 is coupled between the first low pass filter 402 and the signal generation module 104.

On the other hand, the signal generation module 104 includes a clock signal generator unit 708, a counting unit 704, and a digital signal generation unit 706. Wherein, the counting unit 704 is coupled to the clock signal generator unit 708, and the digital signal generation unit 706 is coupled between the counting unit 704 and the ADC 702.

In the step S202 of the present embodiment, after the third pulse signal P3 is filtered by the first low pass filter 402 to generate the first pulse width signal W1 (i.e. DC signal), the ADC 702 receives the first pulse width signal W1 and converts the first pulse width signal W1 to a digital signal (e.g., a digital code) which is further output to the signal generation module 104.

Then, the step S204 may include following processes: first, the clock signal generation unit 708 generates a clock signal T1. The counting unit 704 counts pulses of the clock signal T1 to generate a counting value C1. Next, the digital signal generation unit 706 generates the first signal S1 according to the first pulse width signal W1 and the counting value C1.

For example, FIG. 8 is a schematic diagram illustrating digital signals according to the fifth embodiment of the present invention. Referring to both FIG. 7 and FIG. 8, assuming the duty ratio of the first pulse width signal W1 is 50%, then after converted by the ADC 702, the digital code representing the first pulse width signal W1 (assuming the digital code is 8 bits) is “10000000” (i.e., a decimal number with a value of 128). The counting unit 704 counts a number of the pulses of the clock signal T1 to generate the counting value C1, and when the counting value C1 is accumulated to 256, the counting unit 704 resets the counting value C1 and continues counting the number of the pulses of the clock signal T1. During a period of time when the counting value C1 is not greater than 128, the first signal S1 generated by the digital signal generation unit 706 is high-level. On the contrary, during duration when the counting value C1 is greater than 128, the voltage level of the first signal S1 generated by the digital signal generation unit 706 is low. Accordingly, the first signal S1 with the first duty ratio R1 may be generated. In addition, the signal generator 700 may adjust a frequency of the clock signal T1 generated by the clock signal generation unit 708 so as to acquire the first signal S1 with different frequency.

### The Sixth Embodiment

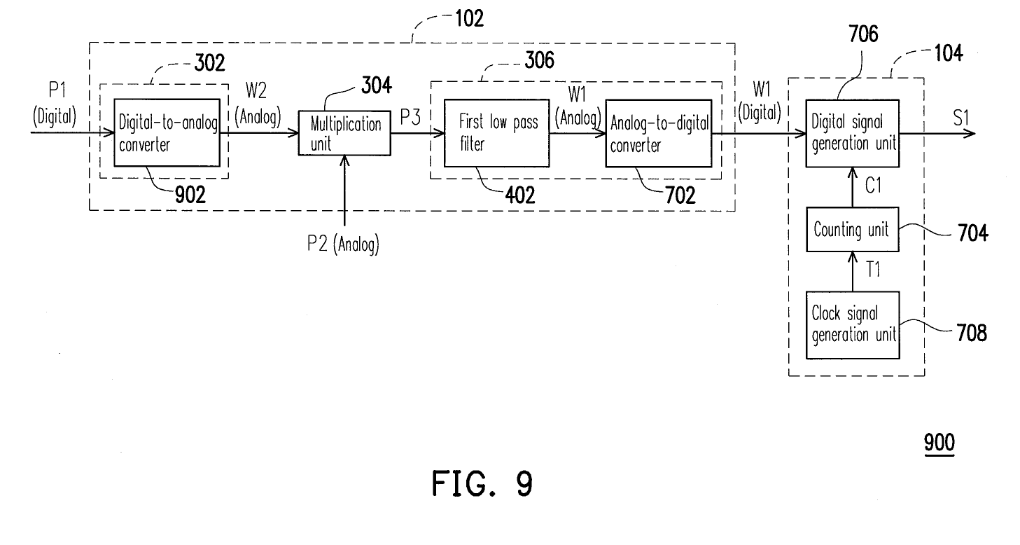

FIG. 9 is a block diagram illustrating a signal generator according to a sixth embodiment of the present invention. Referring to FIG. 9, a difference of the signal generator 900 of the present embodiment and the signal generator 700 of the fifth embodiment is that the first pulse signal P1 is a digital signal (e.g., a digital code), and the second low pass filter 404 of the signal generator 700 is replaced by an DAC 902. Wherein, the DAC 902 is coupled to the multiplication unit 304.

In the present embodiment, when the step S202 of is executed, before the multiplication of the second pulse width signal W2 and the second pulse signal P2, the first pulse signal P1 (i.e. a digital signal) is first converted to the second pulse width signal W2 (i.e. a DC signal) by the DAC 902. Further, the steps of generating the third pulse signal P3, the first pulse width signal W1 and the first signal S1 are identical to the fifth embodiment, so they will not be described herein.

### The Seventh Embodiment

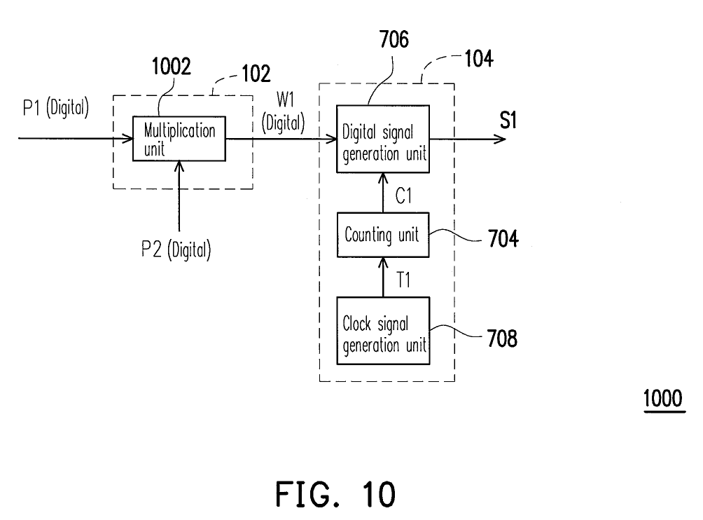

FIG. 10 is a block diagram illustrating a signal generator according to a seventh embodiment of the present invention. Referring to FIG. 10, a difference of a signal generator 1000 of the present embodiment and the signal generator 900 of the sixth embodiment is that the second pulse signal P2 is a digital signal, and the pulse width signal generation module 102 includes a multiplication unit 1002. Wherein, the multiplication unit 1002 is a digital multiplier. The multiplication unit 1002 receives the first pulse signal P1 and the second pulse signal P2, and multiplies the first pulse signal P1 and the second pulse signal P2 to generate the first pulse width signal W1 (the step S202). Further, the method processes of generating the first signal S1 with the first duty ratio are identical to the fifth embodiment, so they will be not described herein.

### The Eighth Embodiment

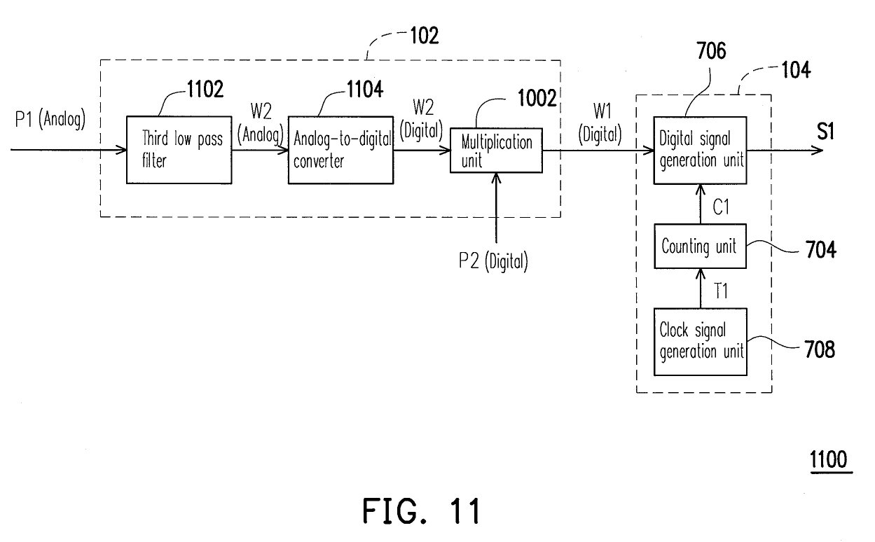

FIG. 11 is a block diagram illustrating a signal generator according to an eighth embodiment of the present invention. Referring to FIG. 11, a difference of a signal generator 1100 of the present embodiment and the signal generator 1000 of the seventh embodiment is that the first pulse signal P1 is an analog signal, and the pulse width signal generation module 102 further includes a third low pass filter 1102 and an ADC 1104. The ADC 1104 is coupled to the third low pass filter 1102 and the multiplication unit 1002.

In the step S202 of the present embodiment, the third low pass filter 1102 filters the first pulse signal P1 to generate the second pulse width signal W2 (i.e. a DC signal). Then, the ADC 1104 receives the second pulse width signal W2 and converts the second pulse width signal W2 to a digital signal (e.g., a digital code) which is further output to the signal generation module 104.

Further, the method processes of generating the first signal S1 with the first duty ratio R1 are identical to the seventh embodiment, so they will be not described herein.

### The Ninth Embodiment

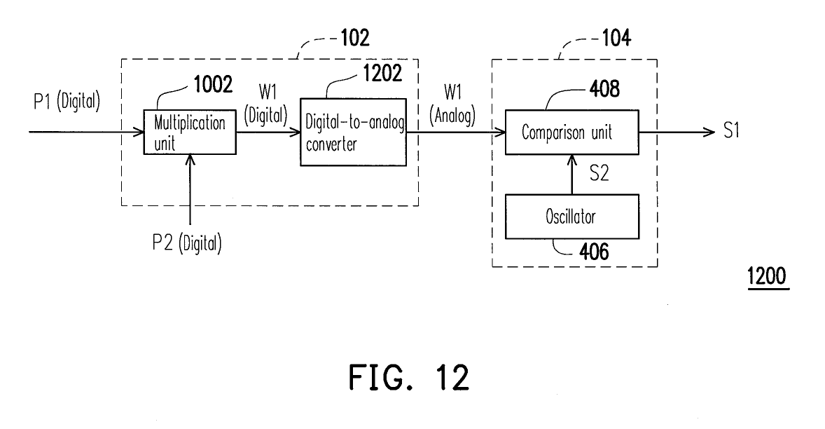

FIG. 12 is a block diagram illustrating a signal generator according to a ninth embodiment of the present invention. Referring to FIG. 12, a difference of a signal generator 1200 of the present embodiment and the signal generator 1000 of the seventh embodiment is that, the pulse width signal generation module 102 further includes a DAC 1202. Wherein, the DAC 1202 is coupled to the multiplication unit 1002 and the signal generation module 104. In addition, the signal generation module 104 in the present embodiment is identical to the third embodiment, including the oscillator 406 and the comparison unit 408. The comparison unit 408 is coupled between the DAC 1202 and the oscillator 406.

In the step S202 of the present embodiment, the DAC 1202 converts the first pulse width signal W1 generated by the multiplication unit 1002 to an analog signal (i.e. a DC signal). Then, identical to the step S204 in the third embodiment, the comparison unit 408 compares the voltage level of the first pulse width signal W1 and the voltage level of the second signal S2 so as to generate the first signal S1 with the first duty ratio R1.

### The Tenth Embodiment

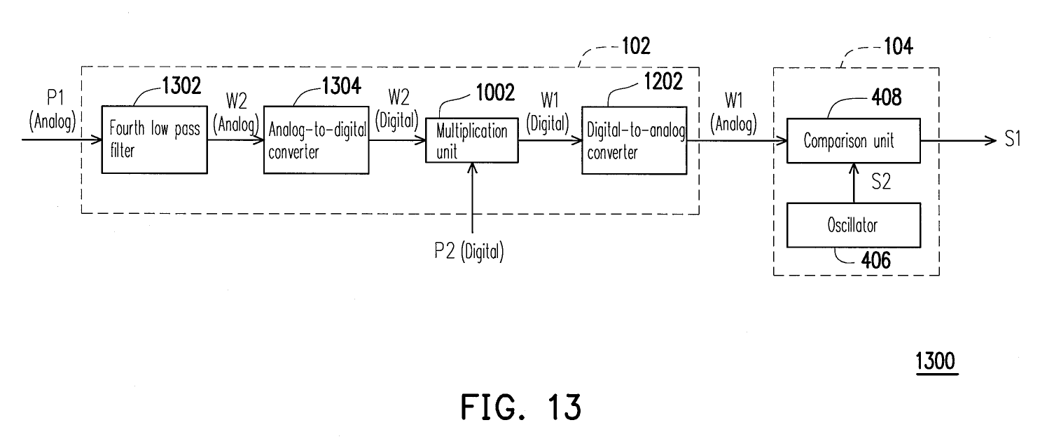

FIG. 13 is a block diagram illustrating a signal generator according to a tenth embodiment of the present invention. Referring to FIG. 13, a difference of a signal generator 1300 of the present embodiment and the signal generator 1000 of the ninth embodiment is that, the pulse width signal generation module 102 further includes a fourth low pass filter 1302 and an ADC 1304. The ADC 1304 is coupled between the, fourth low pass filter 1302 and the multiplication unit 1002.

The fourth low pass filter 1302 receives the first pulse signal P1 and filters the first pulse signal P1 to generate the second pulse width signal W2. Wherein, the second pulse width signal W2 is a DC signal (i.e. an analog signal). Then, the ADC 1304 receives the second pulse width signal W2 and converts the second pulse width signal W2 to a digital signal (e.g., a digital code) which is further output to the multiplication unit 1002. Further, the method processes of generating the first signal S1 with the first duty ratio R1 are identical to the ninth embodiment, so they will be not described herein.

Although, the first signal S1 with the first duty ratio R1 is generated by multiplying two pulse signals in every embodiment described previously, practical applications should not be limited thereto. The methods of the aforementioned embodiments may also be applied in the multiplication of a plurality of pulse signals, and the method of the multiplication of the pulse signals is identical to the method of the multiplication of the two pulse signals.

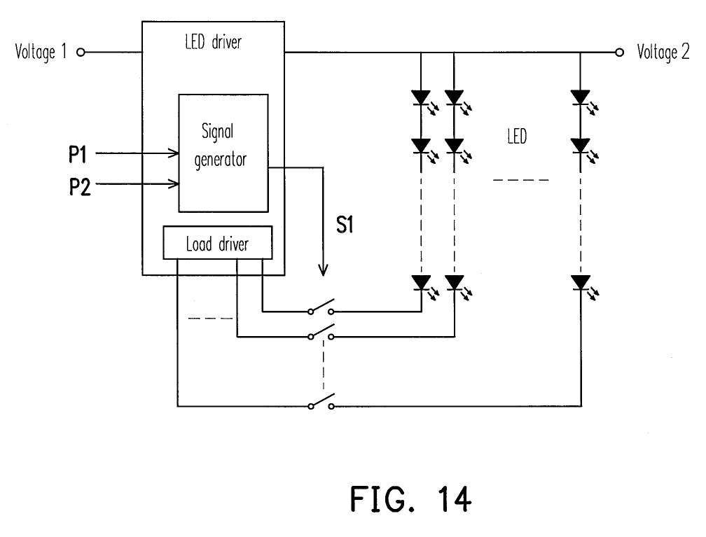

FIG. 14 is a schematic diagram illustrating an application of a signal generator for a monitor brightness adjustment according to an embodiment of the present invention. Referring to FIG. 14, in a light-emitting diode (LED) driver, an LED current at an output stage is adjusted by pulse-width modulation (PWM) so as to adjust an LED brightness is a common brightness adjustment method. A PWM light adjustment signal performs a switching of an output stage driving current, after an filtering effect of human eyes, an LED backlight brightness sensed by the human eyes may be changed, wherein the LED brightness is in a positive proportion to a duty cycle of the PWN light adjustment signal. When a user requires adjust a brightness of a LCD monitor, a PWM signal (i.e. the first pulse signal P1) may be generated through a human machine interface on the LCD monitor, an multiplication of the first pulse signal P1 and the original PWM light adjustment signal (i.e. the second pulse signal P2) is performed through the signal generator such that a control signal (i.e. the first signal S1) is generated to adjust the brightness of the LCD monitor.

In addition, at a low power application requirement, assuming a system detects that it is in a state of a sleeping mode or an energy-saving mode, the system may also automatically send the PWM signal through a control processor such that LED backlight brightness is turned down so as to achieve an energy-saving effect.

In summary, the present invention extracts the duty ratios of the pulse signals of any frequency and any amplitude in forms of a DC signal or a digital signal (e.g., a digital code), and the pulse signals are not limited to analog signals or digital signals. Through the multiplication of the DC signal or the digital signal, the first signal with multiplication information of the duty ratios of the pulse signals may be acquired. In addition, the frequency of the first signal is changed through adjustments of the frequencies of the second signal and the clock signal, and the amplitude of the first signal may also be adjusted when the first signal is an analog signal.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A signal generator, comprising:
a pulse width signal generation module, generating a first pulse width signal according to a first pulse signal and a second pulse signal; and
a signal generation module, coupled to the pulse width signal generation module, generating a first signal with a first duty ratio according to the first pulse width signal, wherein the first duty ratio is equal to a product of a duty ratio of the first pulse signal and a duty ratio of the second pulse signal.

2. The signal generator as claimed in claim 1, wherein the pulse width signal generation module comprises:
a first pulse signal conversion unit, receiving the first pulse signal and converting the first pulse signal to a second pulse width signal;
a multiplication unit, coupled to the first pulse signal conversion unit, receiving the second pulse width signal and the second pulse signal, and multiplying the second pulse width signal and the second pulse signal to generate a third pulse signal; and
a second pulse signal conversion unit, coupled to the multiplication unit and the signal generation module, receiving the third pulse signal to convert the third pulse signal to the first pulse width signal.

3. The signal generator as claimed in claim 2, wherein the second pulse width signal is an analog signal, and a ratio of a voltage level of the second pulse width signal to a peak voltage level of the first pulse signal is equal to the duty ratio of the first pulse signal.

4. The signal generator as claimed in claim 2, wherein the first pulse width signal is an analog signal, and a ratio of a voltage level of the first pulse width signal to a peak voltage level of the second pulse signal is equal to the product of the duty ratio of the first pulse signal and the duty ratio of the second pulse signal.

5. The signal generator as claimed in claim 2, wherein the multiplication unit is an analog mixer.

6. The signal generator as claimed in claim 5, wherein the second pulse signal conversion unit comprises:
a first low pass filter, coupled to the multiplication unit and the signal generation module, receiving the third pulse signal and filtering the third pulse signal to generate the first pulse width signal, wherein the third pulse signal is an analog signal, and the first pulse width signal is a direct current (DC) signal.

7. The signal generator as claimed in claim 6, wherein the first pulse signal conversion unit comprises:
a second low pass filter, coupled to the multiplication unit, receiving the first pulse signal and filtering the first pulse signal to generate the second pulse width signal, wherein the first pulse signal is an analog signal, and the second pulse width signal is a DC signal.

8. The signal generator as claimed in claim 6, wherein the second pulse signal conversion unit further comprises:
an analog-to-digital converter, coupled to the first low pass filter and the signal generation module, receiving the first pulse width signal and converting the first pulse width signal to a digital signal.

9. The signal generator as claimed in claim 6, wherein the first pulse signal conversion unit comprises:
a digital-to-analog converter, coupled to the multiplication unit, receiving the first pulse signal, and converting the first pulse signal to the second pulse width signal, wherein the first pulse signal is a digital signal, and the second pulse width signal is a DC signal.

10. The signal generator as claimed in claim 1, wherein the pulse width signal generation module comprises:
a multiplication unit, coupled to the signal generation module, receiving the first pulse signal and the second pulse signal, and multiplying the first pulse signal and the second pulse signal to generate the first pulse width signal, wherein the second pulse signal is a digital signal.

11. The signal generator as claimed in claim 10, wherein the multiplication unit is a digital mixer.

12. The signal generator as claimed in claim 11, wherein the first pulse signal is a digital signal.

13. The signal generator as claimed in claim 12, wherein the pulse width signal generation module further comprises:
a digital-to-analog converter, coupled to the multiplication unit and the signal generation module, receiving the first pulse width signal and converting the first pulse width signal to an analog signal.

14. The signal generator as claimed in claim 11, wherein the pulse width signal generation module further comprises:
a third low pass filter, receiving the first pulse signal and filtering the first pulse signal to generate a second pulse width signal, wherein the first pulse signal is an analog signal, and the second pulse width signal is a direct current (DC) signal; and
an analog-to-digital converter, coupled to the third low pass filter and the multiplication unit, receiving the second pulse width signal and converting the second pulse width signal to a digital signal.

15. The signal generator as claimed in claim 1, wherein the signal generation module comprises:
an oscillator, periodically generating a second signal; and
a comparison unit, coupled between the pulse width signal generation module and the oscillator, comparing a voltage level of the first pulse width signal and a voltage level of the second signal to generate the first signal, wherein the first pulse width signal and the second signal are analog signals.

16. The signal generator as claimed in claim 15, wherein the second signal is a saw tooth wave.

17. The signal generator as claimed in claim 1, wherein the signal generation module comprises:
a clock signal generation unit, generating a clock signal;
a counting unit, coupled o the clock signal generator unit, counting pulses of the clock signal to generate a counting value; and
a digital signal generation unit, coupled between the pulse width signal generation module and the counting unit, generating the first signal according to the first pulse width signal and the counting value, wherein the first pulse width signal is a digital signal.

18. A signal generating method, comprising:
generating a first pulse width signal according to a first pulse signal and a second pulse signal; and
generating a first signal with a first duty ratio according to the first pulse width signal, wherein the first duty ratio is equal to a product of a duty ratio of the first pulse signal and a duty ratio of the second pulse signal.

19. The signal generating method as claimed in claim 18, wherein the step of generating the first pulse width signal comprises:
converting the first pulse signal to a second pulse width signal; and
multiplying the second pulse width signal and the second pulse signal to generate a third pulse signal; and
converting the third pulse signal to the first pulse width signal.

20. The signal generating method as claimed in claim 18, wherein the step of generating the first pulse width signal comprises:
multiplying the first pulse signal and the second pulse signal to generate the first pulse width signal.

21. The signal generating method as claimed in claim 18, wherein the step of generating the first signal comprises:
generating a second signal periodically; and
comparing a voltage level of the first pulse width signal and a voltage level of the second signal to generate the first signal, wherein the first pulse width signal is an analog signal.

22. The signal generating method as claimed in claim 21, wherein the second signal is a saw tooth wave.

23. The signal generating method as claimed in claim 18, wherein the step of generating the first signal comprises:
counting pulses of a clock signal to generate a counting value; and
generating the first signal according to the first pulse width signal and the counting value, wherein the first pulse width signal is a digital signal.
